(19) United States
(12) Patent Application Publication
(10) Pub. No.: US 2005/0221613 A1
(43) Pub. Date: Oct. 6, 2005

(54) Electrode formation method, electrode and solar battery

(75) Inventors: Ryoh Ozaki, Katsuragi-shi (JP); Hitomi Ohta, Osaka-shi (JP); Hiroyuki Fukumura, Yamatotakada-shi (JP); Yoshiroh Takaba, Shiki-gun (JP); Yuji Komatsu, Kitakatsuragi-gun (JP); Tohru Nunoi, Nara-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/142,331

(22) Filed: Jun. 2, 2005

(30) Foreign Application Priority Data
Apr. 6, 2004 (JP) 2004-167293

(51) Int. Cl. H01L 21/44

(52) U.S. Cl. 438/666; 136/206

(57) ABSTRACT

A method for forming an electrode according to the present invention includes a step of discharging a paste containing an electrode material from a discharge port of a nozzle, and drawing a fine-line pattern on a surface of a semiconductor substrate, and a step of drying and baking the drawn fine-line pattern, and forming a fine-line electrode. Herein, in the drawing step, the nozzle is arranged so that a central axis of the nozzle is inclined at a predetermined inclination angle with respect to the surface of the semiconductor substrate, and so that the discharge port is proximate to the surface of the semiconductor substrate at a predetermined distance, the nozzle and the semiconductor substrate are moved relatively to each other in a drawing direction of the fine-line pattern, and relative movement speeds of the nozzle and the semiconductor substrate are adjusted, thereby drawing the fine-line pattern so that a line width of the fine-line pattern is smaller than an inner diameter of the discharge port of the nozzle.

### CROSS-REFERENCE TO RELATED APPLICATION

This application is related to Japanese application No.2004-167293 filed on Jun. 4, 2004 whose priority is claimed under 35 USC §119, the disclosure of which is incorporated by reference in its entirety.

### BACKGROUND OF THE INVENTION

1. Field of the Invention

The present invention relates to an electrode formation method, an electrode and a solar battery. More specifically, the present invention relates to a method for forming an electrode used in a solar battery or the like, an electrode formed by using this method, and a solar battery including this electrode.

2. Description of the Related Art

Examples of a method for forming an electrode as one of solar battery manufacturing steps include a deposition method, a plating method, a printing method, a drawing method and the like. At present, with a view of cost reduction and mass production in the solar battery, screen printing is widely used.

With this screen printing, a pattern configured by a main electrode (a width of about 1 to 2 mm) and a sub-electrode (a width of about 50 to 200 μm) in perpendicular contact with the main electrode is screen-printed on a light reception surface of an n⁺p type solar battery cell using an Ag paste produced by mixing a solvent with an Ag powder, a glass powder and an organic resin during formation of an electrode on a light reception surface (n⁺ surface). Thereafter, the pattern is dried and baked, thereby forming the light-reception surface electrode. Conventionally, an aspect ratio (height/width) of a cross section of the electrode is about 0.1 to 0.2, and a resistance of the sub-electrode per unit length is approximately 0.25 Ω/cm.

When an electrode on a back surface (a back surface electrode) is formed, a pattern is screen-printed on the back surface almost entirely using an Al paste produced by mixing a solvent with an Al powder, a glass powder and an organic resin. Thereafter, the pattern is dried and baked, thereby forming the back surface electrode. During this back surface electrode formation, a back surface field (BSF) layer is simultaneously formed so as to increase an open-circuit voltage and increase a short-circuit current.

As shown in Japanese Unexamined Patent Publication Nos. SHO 58(1983)-27375 and HEI 6(1994)-29559, there is conventionally known a method of discharging a paste from a nozzle and drawing a pattern. According to the above publications, the nozzle is arranged to be perpendicular to a surface of a substrate. A line width of the drawn pattern can be set to about 100 μm. Each of the drawing methods disclosed therein is considered to be a low-cost method similar to the printing method.

According to a method disclosed in International Patent Application Laid-Open No. 2003-536240, a main electrode is formed using nozzles having different aspect ratios of a shape of a nozzle opening. With this method, the main electrode thicker than the electrode formed by the screen printing can be formed.

In order to improve an efficiency of a solar battery, it is necessary to absorb light to a power generation layer of the solar battery as much as possible, to minimize a resistance loss, and to extract a power. It is known that a line width of the electrode is narrowed and a height of the electrode is increased, that is, an aspect ratio of the electrode is increased so as to meet these requirements.

The screen printing method has, however, the following disadvantages. If the line width of the sub-electrode is narrowed, a screen mesh clogs up and breaking of the line or inability to obtain a predetermined line width occurs. Due to this, it is difficult to narrow the line width of the sub-electrode. In addition, a screen mask is easily broken even by a low impact and care should be therefore taken of to handle the screen mask.

An electrode formation apparatus disclosed in Japanese Unexamined Patent Publication No. HEI 6(1994)-29559 solves disadvantages including a necessity to replace a mask due to a change in the line width of the electrode and the breaking of the screen. However, the line width of the electrode depends on a diameter of the nozzle. If the diameter of the nozzle is reduced so as to narrow the line width of the electrode, the paste clogs up, resulting in breaking of the electrode. With the method disclosed in International Patent Application Laid-Open No. 2003-536240, the main electrode can be formed but the sub-electrode configured to have a smaller electrode width cannot be formed.

### SUMMARY OF THE INVENTION

It is an object of the present invention to provide a method for forming an electrode capable of solving the conventional disadvantages, dispensing with a screen mask, and ensuring a high aspect ratio, and an electrode formed by using this method, and a solar battery including this electrode.

According to one aspect of the present invention, there is provided a method for forming an electrode, comprising steps of: discharging a paste containing an electrode material from a discharge port of a nozzle, and drawing a fine-line pattern on a surface of a semiconductor substrate; and drying and baking the drawn fine-line pattern, and forming a fine-line electrode, wherein in the drawing step, the nozzle is arranged so that a central axis of the nozzle is inclined at a predetermined inclination angle with respect to the surface of the semiconductor substrate, and so that the discharge port is proximate to the surface of the semiconductor substrate at a predetermined distance, the nozzle and the semiconductor substrate are moved relatively to each other in a drawing direction of the fine-line pattern, and relative movement speeds of the nozzle and the semiconductor substrate are adjusted, thereby drawing the fine-line pattern so that a line width of the fine-line pattern is smaller than an inner diameter of the discharge port of the nozzle.

According to another aspect of the present invention, there is provided an electrode formed by using the method according to one aspect of the present invention.

According to still another aspect of the present invention, there is provided a solar battery comprising the electrode according to another aspect of the present invention.

### BRIEF DESCRIPTION OF THE DRAWINGS

FIG. 1 is a front view for describing an inclination angle of a nozzle with respect to a substrate in an electrode formation method according to the present invention;

FIG. 2 is a cross-sectional front view for describing a cross-sectional structure of a solar battery according to the present invention;

FIG. 3 is a flowchart that shows manufacturing steps of the electrode formation method according to the present invention; and

FIG. 4 is a front view of an apparatus employed for the electrode formation method according to the present invention.

### DESCRIPTION OF THE PREFERRED EMBODIMENTS

With the electrode formation method according to the present invention, the paste containing the electrode material is discharged from the discharge port of the nozzle and the fine-line pattern is drawn on the surface of the semiconductor substrate. It is thereby possible to dispense with the screen mask required in the printing method. Further, the nozzle and the substrate are relatively moved in the drawing direction of the fine-line pattern, whereby the electrode having a higher ratio of the height to the width, i.e., a higher aspect ratio can be obtained.

Moreover, the relative movement speeds (drawing speeds) of the nozzle and the substrate are adjusted, and the finer-line electrode is formed, thereby increasing an effective power generation area. Consequently, current increases and the efficiency of the solar battery can be improved.

Further, the nozzle is arranged so that the nozzle is inclined at the predetermined inclination angle with respect to the surface of the substrate and so that the discharge port of the nozzle is proximate to the surface of the substrate at the predetermined distance. It is therefore possible to prevent breaking of lines of the electrode when the drawing speed is set higher.

Since the electrode according to the present invention is formed by the electrode formation method according to the present invention, the electrode has a high aspect ratio. Since the electrode is formed to be narrower, the effective power generation area is increased. Therefore, the current increases and the efficiency of the solar battery including this electrode can be eventually improved.

The solar battery according to the present invention comprises the finer-line electrode according to the present invention. Therefore, the effective power generation area is increased. Accordingly, the current increases and the efficiency of the solar battery comprising this electrode can be eventually improved.

In one example of an electrode formation method according to the present invention, a nozzle is made stationary and a substrate is then moved, and a moving speed of the substrate (a relative movement speed of the substrate to the nozzle) is set higher than a speed at which a paste is discharged from the nozzle. According to such an electrode formation method, the substrate is moved at the higher speed than the speed of discharging the paste from the nozzle and a pattern is drawn. It is thereby possible to further expand the discharged paste and provide finer lines of the pattern. In addition, since the drawing speed is set higher, it is possible to ensure high throughput and improve productivity.

In another example of the electrode formation method according to the present invention, the substrate is made stationary and the nozzle is then moved, and a moving speed of the nozzle (a relative movement speed of the nozzle to the substrate) is set higher than the speed at which the paste is discharged from the nozzle. According to such an electrode formation method, the nozzle is moved at the higher speed than the speed of discharging the paste from the nozzle and the pattern is drawn. It is thereby possible to further expand the discharged paste and provide finer lines of the pattern. In addition, since the drawing speed is set higher, it is possible to ensure high throughput and improve productivity.

In still another example of the electrode formation method according to the present invention, the nozzle and the substrate are moved so as to be away from each other, and relative movement speeds of the nozzle and the substrate are adjusted to be higher than the speed at which the paste is discharged from the nozzle. According to such an electrode formation method, the pattern is drawn while the nozzle and the substrate are moved relative to each other at the higher speeds than the speed of discharging the paste from the nozzle. It is thereby possible to further expand the discharged paste and provide finer lines of the pattern. In addition, since the drawing speed is set higher, it is possible to ensure high throughput and improve productivity.

In the electrode formation method according to the present invention, the nozzle is arranged to be inclined at a predetermined angle with respect to a surface of the substrate. The predetermined angle is preferably within a range between 20° and 80°. Namely, the inclination angle of the nozzle with respect to the substrate is preferably smaller so as to eliminate breaking of lines, and greater (the distance between the surface of the substrate and a nozzle discharge port is preferably smaller) so as to set a drawing start point with higher accuracy. The practical nozzle inclination angle is within a range between 20° and 80°, at which angle the electrode having a high aspect ratio can be formed.

A paste that is an electrode material used in the electrode formation method according to the present invention contains metal, glass frits and the like. For example, a baked paste baked at a high temperature, e.g., about 600° C., a thermosetting paste that contains metal, epoxy resin and the like and that is baked at a low temperature, e.g., about 100° C., or the like can be used.

Such a paste preferably has a viscosity within a range between 5 Pa.s (pascal.second) and 3000 Pa.s. By setting the viscosity of the paste used therein to be equal to or more than 5 Pa.s, an electrode width can be further narrowed without excessively spreading the paste on the substrate after application of the paste. By setting the viscosity to be equal to or less than 3000 Pa.s, it is possible to suppress a deterioration in yield resulting from a breaking failure caused by nozzle clogging. If the viscosity of the paste falls within the above range, it is possible to prevent the drawing speed from becoming excessively low. The viscosity of the paste is more preferably within a range between 100 Pa.s and 1000 Pa.s. Herein, it is possible to realize both a reduction in the electrode width and high-speed drawing. In addition, by setting the viscosity to be higher than 1000 Pa.s, an aspect ratio exceeding 0.70 can be obtained.

The aspect ratio (height/line width) of a cross section of the fine-line electrode is preferably within a range between 0.30 and 0.80 in the electrode according to the present invention. If the electrode having the aspect ratio in such a range is used in a solar battery, high conversion efficiency can be ensured.

The electrode according to the present invention preferably contains at least a metal component so as to improve a conductivity.

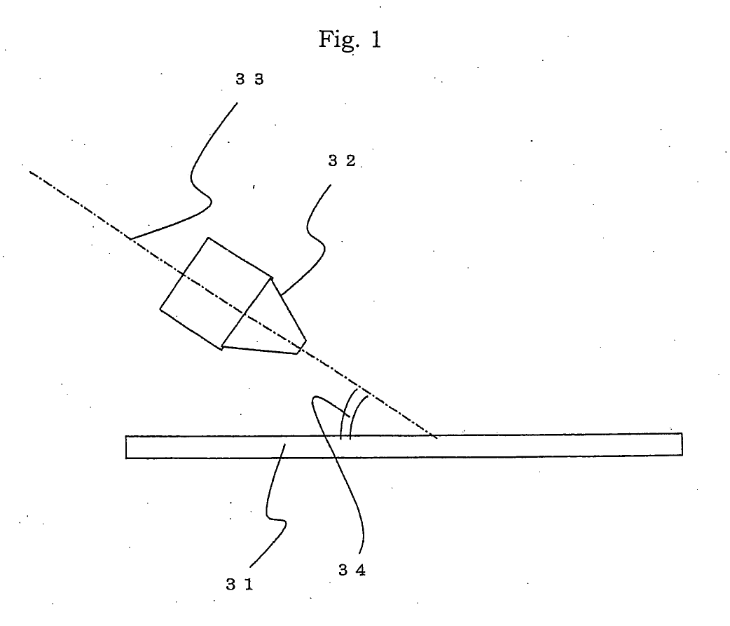

To form the electrode according to the present invention, the drawing method is used as shown in FIG. 1. Namely, a paste discharge nozzle 32 is made stationary and a substrate 31 is configured to be moved rightward on a sheet of FIG. 1. In addition, an angle (a nozzle inclination angle) 34 formed between a central axis 33 of the nozzle 32 and a surface of the substrate 31 is set between 20° and 80°. A movement speed of the substrate 31 is set higher than a speed of discharging the paste from the nozzle 32. With the above configuration, the paste can be applied suitably on the surface of the substrate 31.

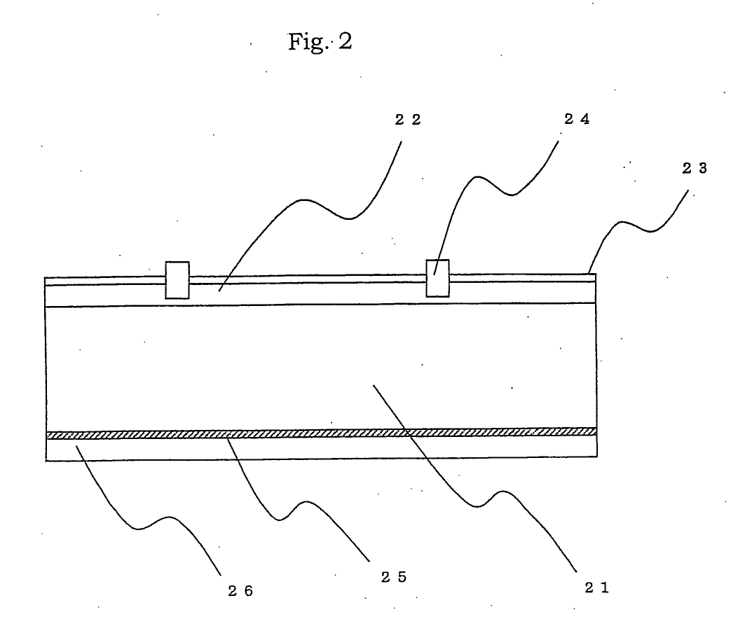

A structure of a solar battery according to the present invention will next be described with reference to FIG. 2 which shows a cross-sectional structure of the solar battery. As a substrate 21, there is used a p type silicon substrate that is a first conductive layer obtained by slicing a silicon ingot by a multi-wire saw slicing method according to a casting process, or a p type single crystal silicon substrate obtained by slicing an ingot by a CZ method or an FZ method.

On a light reception surface, an n type second conductive layer 22 is formed. An antireflection film 23 is formed on a surface of the n type second conductive layer 22. A light reception surface electrode 24 is formed by the drawing method. A resistance of a baked electrode per unit length when drawing a pattern using a baked paste is, for example, 0.15 to 0.20 Ω/cm. On an entire back surface of the substrate 21, a back surface p⁺ layer 25 and a back surface electrode 26 are formed. The back surface p⁺ layer 25 can be configured to obtain a back surface field (BSF) effect. Further, to increase internal reflection of the back surface, the back surface electrode 26 can be configured to serve as a so-called back surface reflecting layer.

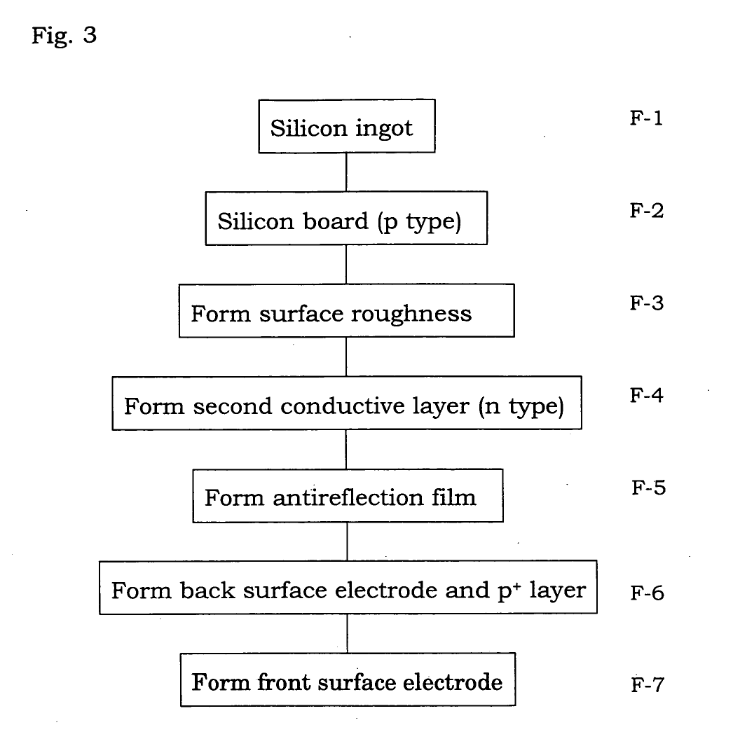

A flow of an entire process of manufacturing a typical solar battery to which the present invention can be applied will be described with reference to FIG. 3.

First, an ingot having a semiconductor characteristic serving as a silicon ingot (F-1) and obtained by the FZ method, the CZ method, the casting method or the like is sliced off by the multi-wire saw slicing method, thereby preparing the p type silicon board serving as a first conductive layer (F-2). Surface roughness is formed on at least one light incidence-side surface of the substrate (F-3). A second conductive layer (n type) is formed (F-4) and an antireflection film is formed (F-5). A back surface electrode and a p⁺ layer are formed (F-6), and a front surface electrode is formed (F-7), thus completing the solar battery.

At present, the solar battery manufacturing process described above is normally used for manufacturing a polycrystalline silicon solar battery or the like. Manufacturing steps of the process can be changed, and a process using a vacuum can be partially adopted. In F-7, the electrode and the electrode formation method according to the present invention can be applied.

According to the present invention, a substrate other than the silicon substrate, such as a compound semiconductor substrate, e.g., a silicon-germanium substrate or a gallium-arsenide substrate made of well-known materials can be employed. As a basic structure of the substrate, either an n type substrate and a p type layer or a p type substrate and an n type layer can be provided in this order on the light incidence side. Alternatively, the n type substrate on the light incidence side may be replaced by a high concentration n⁺ substrate or the p type substrate on the light incidence side may be replaced by a high concentration p⁺ substrate. The second conductive layer may be formed by a conventionally used thermal diffusion method, ion implantation method or the like.

On a surface of the second conductive layer, another antireflection film may be additionally provided. On the back surface opposite to the light incidence-side surface, not only the BSF layer but also a back surface reflecting layer (back surface reflector) and an oxide film or a nitride film for preventing surface recombination may be formed. As the antireflection film and the back surface reflector, various types of oxide films and the like can be used.

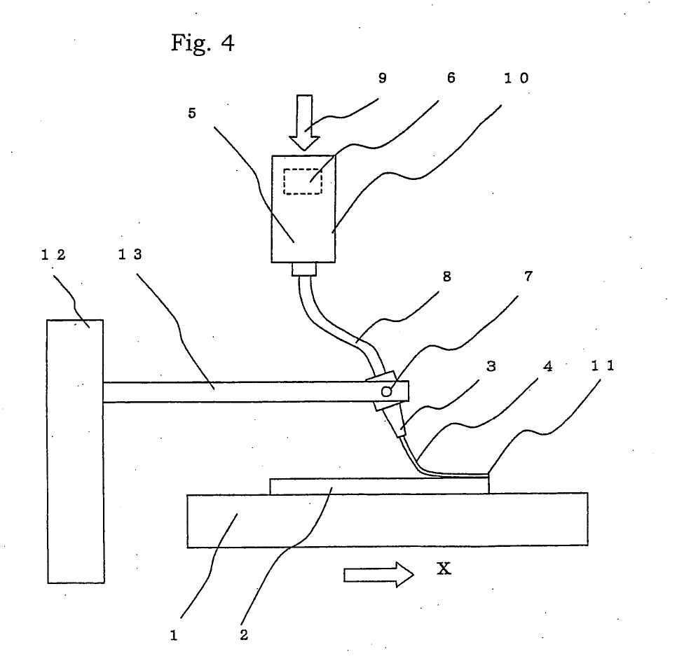

An apparatus for forming the light reception surface electrode according to the present invention is configured as follows. As shown in FIG. 4, a table 1 which can be moved along an X axis and a Y axis (note that the Y axis is not shown in FIG. 4 but extends in a depth direction of the sheet of FIG. 4 orthogonally to the X axis), and on/to which a silicon substrate 2 can be mounted/fixed, a nozzle 3 fixedly provided above the table 1 by an angle variable part 7, and a syringe 10 filled with a paste 5 made of a conductive electrode material are held by a means (not shown). The apparatus also includes a piston 6 movable in close contact with an inner surface of the syringe 10, a pressure-proof tube 8 having both ends connected to the nozzle 3 and the syringe 10, respectively, and a pressurization mechanism 9 that can movably pressurizes the piston 6. Using the apparatus configured as described above, the electrode according to the present invention is formed. It is noted that holding parts 12 and 13 are provided to hold the nozzle 3.

A basic electrode pattern drawing operation will be described. When the piston 6 is pressurized, the paste 5 filed into-the syringe 10 is pushed out and discharged from a discharge port provided on a tip end of the nozzle 3. Drawing is started from one end 11 of the silicon substrate 2 fixedly mounted on the table 1 and configured so that a first conductive layer, a second conductive layer and an SiN layer are sequentially provided in this order. At the same time, the table 1 on/to which the silicon substrate 2 is fixedly mounted/fixed is moved at a predetermined speed in an X direction (a fine-line pattern drawing direction). It is thereby possible to continuously and linearly draw a fine-line pattern of the paste 4 on the surface of the silicon substrate 2 from one end 11 to the other end of the silicon substrate 2. Next, the table 1 is moved in a depth direction of the sheet of FIG. 4 along the Y axis extending in the depth direction by as much as a distance between sub-electrodes. At the same time, the table 1 is returned to the start point on the X axis. The linear pattern is drawn similarly to the above.

By repeating the operation described above, the fine-line pattern of the paste 4 serving as the sub-electrode is drawn on the surface of the silicon substrate 2. Alternatively, the pattern can be drawn while moving the nozzle 3 without moving the table 1 or while moving both the table 1 and the nozzle 3 in opposite directions to each other.

By setting a movement speed of the table 1 in the X direction higher than a speed at which the paste 5 is discharged from the nozzle 3, a diameter of a cross section of the discharged paste 4 can be made smaller than an inner diameter of the discharge port of the nozzle 3. For example, even when the diameter of the cross section of the paste 4 just discharged from the discharge port of the nozzle 3 is 100 μm which is equal to the inner diameter of the discharge port of the nozzle 3, the later diameter of the cross section of the paste 4 can be set to about 71 μm, which is 1/(√2)≈0.71 time as large as the inner diameter of the discharge port of the nozzle 3 by setting the movement speed of the table 1 to be twice as high as the paste discharge speed.

As for the paste having a molecular particle diameter of about 1 to 5 μm, containing at least a metal component, and having a viscosity of, e.g., 2000 Pa.s, the movement speed of the silicon substrate 2, at which a ratio of a cross-sectional area of the paste landing on the surface of the silicon substrate 2 to the cross-sectional area thereof at the discharge port of the nozzle 3 is 1/50, is about 1000 mm/sec.

If the angle variable part 7 sets the inclination angle of the nozzle 3 with respect to the surface of the silicon substrate 2 to be close to a right angle, a cross-sectional shape of the paste discharged from the discharge port of the nozzle 3 is elliptic since the table 1 is moved at high speed. The height of the cross section of the paste is smaller accordingly. If the angle variable part 7 sets the inclination angle of the nozzle 3 to be smaller, the cross-sectional shape of the paste is closer to a circle and the high aspect ratio (height/width) can be obtained.

A distance between the discharge port of the nozzle 3 and the surface of the silicon substrate 2 can be set within a range between 0.5 mm and 30 mm, preferably between 0.5 mm and 5 mm. If the distance is within this range, a space sufficient to pull the paste is formed between the discharge port of the nozzle 3 and the silicon substrate 2. A finer-line electrode can be therefore formed. The nozzle 3 is preferably made of metal and is configured so that paste discharge fine bores are formed. A diameter of the fine bore can be set to 20 μm to 500 μm. The diameter of the fine bore is preferably 50 μm to 100 μm so as to provide the fine-line electrode and prevent nozzle clogging.

Needless to say, the present invention is applicable to an instance in which many nozzles are arranged so that a plurality of electrode patterns can be simultaneously drawn instead of drawing the electrode pattern of the solar battery using the single nozzle. Further, as the nozzle used herein, a hard nozzle made of SUS, glass or the like can be used. An inner surface of the nozzle can be processed to provide smooth discharge of the paste. As for the main electrode, any of various methods including the printing method and the drawing method can be formed.

A material for the paste for forming the light reception surface electrode is not limited to the specific one as long as the material is a conductive material. The light reception surface electrode can be formed by a singe layer or plural layers made of one of metals such as gold, platinum, silver, copper, aluminum, nickel, chromium, tungsten, iron, tantalum, titanium and molybdenum, alloys thereof, transparent conductive materials such as SnO₂, In₂O₃, ZnO and ITO, or by using both the metal and the alloy. The light reception surface electrode can be formed by preparing the paste in a powdery state and printing and baking the paste. The paste can be prepared by mixing up, for example, metal, glass frits, organic resin and a solvent.

The back surface electrode is normally formed on the entire back surface. Alternatively, a grid-like back surface electrode can be formed. In this case, the so-called back surface reflecting layer can be formed on a portion of the back surface other than the portion on which the grid-like electrode is formed.

### EXAMPLE 1

The solar battery cell shown in Example 1 generally has the cross-sectional structure shown in FIG. 2. The manufacturing of this cell was based on the flowchart shown in FIG. 3.

First, the p type polycrystalline silicon substrate 21 obtained by slicing the silicon ingot and having an outer size of 10×10 cm, a thickness of 0.35 mm and a specific resistance of about 2 Ωcm was prepared. The surface of the silicon substrate 21 was etched by a depth of 20 μm at 80° C. for 10 minutes in a solution obtained by adding 7% alcohol to a 5% NaOH alkaline aqueous solution. Surface roughness was formed simultaneously with removal of a pulverized layer. Although a height of the surface roughness was around 5 μm to 10 μm microscopically, the silicon substrate 21 was flat as a whole.

Next, the etched silicon substrate 21 was mounted on a jig in an electric furnace at 840° C. in a POCl₃ containing atmosphere, and phosphorus ions were diffused onto the silicon substrate 21 for 20 minutes, thereby forming the n⁺ layer 22 on the surface of the silicon substrate 21. After removing a PSG (phosphorus silicate glass) layer and the like from the resultant substrate 21 in a HF aqueous solution, washing and drying were performed to thereby obtain the light reception surface-side n⁺ type diffusion layer 22 having a sheet resistance of 60 Ω/cm, a junction depth of about 0.3 μm, a near-surface dopant concentration of about 10²⁰ cm⁻³. Using a plasma CVD device, an SiN layer serving as the antireflection film 23 was formed on the surface of the n⁺ diffusion layer 22. A thickness of the SiN layer was 720 angstroms. As gas materials, silane and ammonium were used.

To form the back surface BSF layer, a paste containing an Al powder was printed and dried on the back surface of the silicon substrate 21. By baking the paste in a near-infrared furnace, the p⁺ layer and the back surface electrode were obtained.

The main electrode was obtained by printing and drying the paste by a width of about 2 mm in a direction orthogonal to the sub-electrode by the screen printing before drawing the sub-electrode pattern. Next, the light reception surface-side surface electrode was formed under conditions that the inner diameter of the discharge port of the nozzle was 150 μm, a discharge pressure was 5 kg/cm², the viscosity of the paste was 100 Pa.s and a fine-line electrode pitch was 2.5 mm.

The main substrate pattern was drawn under conditions that the inclination angles of the nozzle were set to 20°, 40°, 60° and 80°, respectively. Under these condition, the speed at which the paste is discharged from the nozzle was almost equal to 45 mm/sec whereas the movement speed of the table was set to 100 mm/sec. Thereafter, the line width of the electrode formed by baking the paste at about 700° C. measured about 110 μm.

The aspect ratio differed according to the inclination angle of the nozzle as shown in Table 1 below. The specific resistance of the electrode was almost equal to 0.20 Ω/cm. At the nozzle inclination angle of 90°, many broken lines were recognized and the solar battery cell could not be therefore provided.

Thereafter, a current-voltage characteristic of the manufactured solar battery cell was measured under a pseudo solar light having a radiation intensity of 100 mW/cm² (JIS standard light AM 1.5G).

### COMPARATIVE EXAMPLE 1

Comparative Example 1 in which the speed at which the paste is discharged from the nozzle is set equal to the movement speed of the table will be described (see Table 1). In Comparative Example 1, conditions were the same as those according to Example 1 except that the both speeds were equally set to 45 mm/sec and that the inclination angle of the nozzle with respect to the surface of the substrate was 20°. As a result, the line width after baking was about 185 μm, which was larger than the inner diameter of the discharge port of the nozzle, 150 μm. The reasons are considered as follows. Since the paste is pressurized and then discharged, the diameter of the paste right after being discharged from the discharge port of the nozzle is larger than the inner diameter of the discharge port of the nozzle. In addition, since the movement speed of the table is lower than that in Example 1, the paste is expanded insufficiently.

### COMPARATIVE EXAMPLE 2

In Comparative Example 2, a solar battery having a sub-electrode and a main electrode formed simultaneously by the printing method using one screen pattern was manufactured (see Table 1). In Comparative Example 2, a length of the sub-electrode was 48 mm and a line width thereof was a practically minimum width based on the printing method having a tip end width and a bottom width of 140 μn. The other conditions were the same as those in Example 1.

TABLE 1

| | Nozzle | Discharge | Table | | | | | |
|---|---|---|---|---|---|---|---|---|
| | angle | speed | speed | Aspect | J_{sc} | V_{oc} | | E_{ff} |
| | (°) | (mm/sec) | (mm/sec) | ratio | (mA/cm²) | (mV) | F.F | (%) |
| Nozzle cell | 20 | 45 | 100 | 0.35 | 30.9 | 596.2 | 0.783 | 14.5 |
| | 40 | 45 | 100 | 0.32 | 30.7 | 597.4 | 0.774 | 14.3 |
| | 60 | 45 | 100 | 0.30 | 30.4 | 595.6 | 0.772 | 14.1 |
| | 80 | 45 | 100 | 0.29 | 29.7 | 594.1 | 0.767 | 13.8 |
| Comparative | 20 | 45 | 45 | 0.34 | 28.9 | 593.5 | 0.779 | 13.5 |
| Example 1 | | | | | | | | |
| Comparative | Printing | — | — | 0.16 | 29.5 | 594.4 | 0.764 | 13.6 |
| Example 2 | | | | | | | | |

As evident from Table 1, if the inclination angle of the nozzle (nozzle angle) with respect to the surface of the substrate is set smaller, the higher aspect ratio can be obtained. In addition, if the aspect ratio is higher, a current density (Jsc) and a fill factor (F.F) are higher and conversion efficiency is eventually higher. Further, as for the cell according to Comparative Example 1, the aspect ratio near that of the electrode at the nozzle angle of 20° is obtained. However, since the line width is larger, the current density (Jsc) is lower than that of the electrode at the nozzle angle of 20°. In Comparative Example 2, the solar battery cell manufactured by the conventional screen printing method is formed. The nozzle electrode cell manufactured according to the present invention is superior in efficiency to the solar battery cell according to the second comparison embodiment.

### EXAMPLE 2

In Example 2, manufacturing conditions were the same as those according to Example 1 except that the thickness of the p type polycrystalline silicon substrate 21 was 0.15 mm and the nozzle angle was 20°. As a result, a line width and an aspect ratio were about 110 μm and 0.35 similar to those according to Example 1 (see Table 2).

### COMPARATIVE EXAMPLE 3

Similarly to Example 2, the thickness of the p type polycrystalline silicon substrate 21 was 0.15 mm. The sub-electrode and the main electrode were simultaneously formed by the printing method using one screen pattern (see Table 2).

TABLE 2

| | Thickness | | | | | | |
|---|---|---|---|---|---|---|---|
| | of | | J_{sc} | | | | |
| | substrate | Aspect | (mA/ | V_{oc} | | E_{ff} | |
| | (mm) | ratio | cm²) | (mV) | F.F | (%) | Yield |
| Nozzle cell | 0.15 | 0.35 | 30.5 | 597.2 | 0.78 | 14.3 | 10/10 |
| | 0.35 | 0.35 | 30.9 | 596.2 | 0.783 | 14.5 | 10/10 |
| Comparative | 0.15 | 0.28 | 29.0 | 595.1 | 0.772 | 13.4 | 4/10 |
| Example 3 | | | | | | | |

If the surface electrode is formed by the printing method, a stress is applied to the substrate by a print pressure or the like. If a thin solar battery is to be manufactured, in particular, the substrate is greatly warped when the back surface electrode is formed on the entire back surface of the substrate or after the back surface substrate is formed. Due to this, even a low print pressure causes breaking and cracking of the substrate, resulting in a reduction in yield (see Table 2). If the drawing method is used, by contrast, the stress is not applied to the substrate since no print pressure is generated. Therefore, the reduction in yield can be avoided. Further, with the drawing method, the electrode having a high aspect ratio can be formed. Needless to say, therefore, a serial resistance can be reduced.

1. A method for forming an electrode, comprising steps of:
discharging a paste containing an electrode material from a discharge port of a nozzle, and drawing a fine-line pattern on a surface of a semiconductor substrate; and
drying and baking the drawn fine-line pattern, and forming a fine-line electrode, wherein in the drawing step, the nozzle is arranged so that a central axis of the nozzle is inclined at a predetermined inclination angle with respect to the surface of the semiconductor substrate, and so that the discharge port is proximate to the surface of the semiconductor substrate at a predetermined distance, the nozzle and the semiconductor substrate are moved relatively to each other in a drawing direction of the fine-line pattern, and relative movement speeds of the nozzle and the semiconductor substrate are adjusted, thereby drawing the fine-line pattern so that a line width of the fine-line pattern is smaller than an inner diameter of the discharge port of the nozzle.

2. The method according to claim 1, wherein
the relative movement of the nozzle and the semiconductor substrate to each other is to make the nozzle stationary and then move the semiconductor substrate, and the relative movement speed of the semiconductor substrate relative to the nozzle is adjusted to be higher than a speed at which the paste is discharged from the nozzle.

3. The method according to claim 1, wherein
the relative movement of the nozzle and the semiconductor substrate to each other is to make the semiconductor substrate stationary and then move the nozzle, and the relative movement speed of the nozzle relative to the semiconductor substrate is adjusted to be higher than a speed at which the paste is discharged from the nozzle.

4. The method according to claim 1, wherein
the relative movement of the nozzle and the semiconductor substrate to each other is to move the nozzle and the semiconductor substrate so that the nozzle and the semiconductor substrate are away from each other, and the relative movement speeds of the nozzle and the semiconductor substrate are adjusted to be higher than a speed at which the paste is discharged from the nozzle.

5. The method according to claim 1, wherein
the predetermined inclination angle is within a range between 20° and 80°.

6. The method according to claim 1, wherein
the predetermined distance is within a range between 0.5 mm and 30 mm.

7. The method according to claim 1, wherein
the semiconductor substrate is one of a silicon substrate, a silicon-germanium substrate and-a gallium-arsenide substrate.

8. The method according to claim 1, wherein
the paste contains a metallic component and has a viscosity between 5 Pa.s and 3000 Pa.s.

9. An electrode formed by using the method according to claim 1.

10. The electrode according to claim 9, wherein
an aspect ratio of a cross section of the electrode is within a range between 0.30 and 0.80.

11. The electrode according to claim 9, wherein
the electrode contains at least a metal component.

12. A solar battery comprising the electrode according to claim 9.
